(19) United States
(12) Patent Application Publication
(10) Pub. No.: US 2015/0194193 A1
(43) Pub. Date: Jul. 9, 2015

(54) MEMORY AND READING METHOD THEREOF, AND CIRCUIT FOR READING MEMORY

(71) Applicant: Shanghai Huahong Grace Semiconductor Manufacturing Corporation, Shanghai (CN)

(72) Inventors: Shengbo ZHANG, Shanghai (CN); Guangjun YANG, Shanghai (CN); Jun XIAO, Shanghai (CN)

(73) Assignee: Shanghai Huahong Grace Semiconductor Manufacturing Corporation, Shanghai (CN)

(21) Appl. No.: 14/584,887

(22) Filed: Dec. 29, 2014

(30) Foreign Application Priority Data
Jan. 7, 2014 (CN) 201410005972.X

(51) Int. Cl. G11C 7/06

(52) U.S. Cl. CPC G11C 7/062

(57) ABSTRACT

Memory and reading method thereof, and circuit for reading memory are provided. The memory includes a memory array; a row decoding circuit configured to apply word line voltage to selected word line in reading operation; a column decoding circuit configured to select a source line connected with a target memory cell based on reading data, the target memory cell using the selected word line; and a reading circuit including first and second input terminals and a comparison node, the first input terminal being connected with the source line of the memory cell through the column decoding circuit and configured to let in reading current of the target memory cell, the second input terminal being configured to let in base current, the comparison node being configured to compare reading current with reference current related to the base current to output reading result. The memory is driven under low voltage.

### CROSS-REFERENCE TO RELATED APPLICATIONS

The present application claims priority to Chinese patent application No. 201410005972.X, filed on Jan. 7, 2014, and entitled “MEMORY AND READING METHOD THEREOF, AND CIRCUIT FOR READING MEMORY”, and the entire disclosures of which is incorporated herein by reference.

### TECHNICAL FIELD

The present disclosure generally relates to semiconductor technology field, and more particularly, to a memory and a reading method thereof, and a circuit for reading a memory.

### BACKGROUND

Memory is a fundamental part of a digital integrated circuit and also an indispensible part of an application system which is constructed based on a microprocessor. Recently, various memories are embedded into processors to improve an integration level and operation efficiency of the processors. Therefore, performance of a memory array and its peripheral circuit mainly determines operation efficiency of a whole system.

A reading circuit is an essential part of a peripheral circuit of a memory, which is generally used to sample and amplify micro signals on a bit line of a memory cell in the memory when the memory cell is read, to determine information stored in the memory cell.

The reading circuit is configured to compare a current or a voltage of the bit line of the memory cell in the memory with a base current or voltage to read data stored in the memory cell. Specifically, main functions of the reading circuit in the memory are described as follows.

First, the reading circuit has an amplifying function. The reading circuit amplifies a micro signal difference between the current or voltage of the bit line and the base current or voltage to standard logic electric levels 0 and 1 and output the logic electric levels.

Besides, the reading circuit can accelerate state conversion of the bit line to compensate fan-out driving ability of the memory cell, thereby improving performance and rate of the memory cell.

Besides, the reading circuit can effectively decrease a voltage amplitude of the bit line to reduce power consumption in charging and discharging of the bit line.

A working process of the reading circuit includes a pre-charging stage and a comparison stage. In the pre-charging stage, a bit line of a selected memory cell is pre-charged. Electric potential of the bit line is promoted to a value that can generate a bit line current high enough in the selected memory cell. In the comparison stage, a current or voltage of the bit line is compared with a base current or voltage to output a standard logic electric level, thus, a bit line signal is amplified and data is prone to be read.

FIG. 1 illustrates a structural diagram of a memory array in a memory in existing techniques. Referring to FIG. 1, only a part of the memory array is illustrated. The memory array includes memory cells 100 to 115, word lines WL0 to WL3, bit lines BL0 to BL3 and a source line SL0.

The memory cells 100 to 103 are arranged in one row, the memory cells 104 to 107 are arranged in one row, the memory cells 108 to 111 are arranged in one row, and the memory cells 112 to 115 are arranged in one row. The memory cells 100, 104, 108 and 112 are arranged in one column, the memory cells 101, 105, 109 and 113 are arranged in one column, the memory cells 102, 106, 110 and 114 are arranged in one column, and the memory cells 103, 107, 111 and 115 are arranged in one column. The memory cells in one row share one word line, and the memory cells in one column share one bit line. The memory cells 100 to 115 share the source line SL0.

FIG. 2 illustrates a structural diagram of a reading circuit in a memory in existing techniques. Referring to FIG. 2, the reading circuit includes: a comparison unit 200 including a positive terminal 201 and a negative terminal 202; a pre-charging circuit 203 connected in parallel with the comparison unit 200; a clamping circuit 204 connected in series with a parallel connection node between the comparison unit 200 and the pre-charging circuit 203; a column decoding circuit 205 connected in series with the clamping circuit 204 and connected with memory cells; a row decoding circuit 206 connected with the memory cells; and a base unit 207 configured to generate a base voltage Ref to the positive terminal 201, where a selected memory cell is connected with the negative terminal 202 through the column decoding circuit 205, a first control transistor M1 and a second control transistor M2.

A process for reading the memory which includes the memory array in FIG. 1 and the reading circuit in FIG. 2 is described as follows.

For example, the memory cell 100 in FIG. 1 is selected. When the reading circuit works in a pre-charging stage, the column decoding circuit 205 selects the bit line BL0 of the memory cell 100, and the source line SL0 of the memory cell 100 is grounded (or connected to a low electric level). The row decoding circuit 206 applies a word line voltage to the word line WL0. At the same time, the pre-charging circuit 203 starts to charge the bit line BL0 through the clamping circuit 204 and the column decoding circuit 205, until a bit line voltage of the bit line BL0 reaches a predetermined clamping voltage.

After the pre-charging stage ends, a comparison stage is started. The first control transistor M1 and the second control transistor M2 are conductive, so that the bit line voltage Mat is accessed to the negative terminal 202 of the comparison unit 200. The bit line voltage Mat is compared with a base voltage Ref that is accessed to the positive terminal 201 of the comparison unit 200, and a comparison result Sout, which reflects data stored in the memory, is output from an output terminal of the comparison unit 200.

However, the above memory may have following disadvantages. First, a power supply may have a relatively high voltage. As shown in FIG. 2, the voltage VDD of the power supply has to provide a driving voltage for the memory cell 100, the first control transistor M1 and the second control transistor M2 which are connected in series with one other in one branch at the same time. For example, a voltage difference between a source line voltage and a bit line voltage of the memory cell 100 is Vdr, a source-drain voltage difference of the first control transistor M1 is Vds1, and a source-drain voltage difference of the second control transistor M2 is Vds2, thus, the voltage VDD of the power supply should be maintained at least at (Vdr+Vds1+Vds2). Besides, the pre-charging stage included in the process for reading the memory requires a certain charging time period, which may affect a reading rate of the memory, and causes energy consumption. Besides, a driving voltage of a control terminal of the column decoding circuit in the memory is relatively high, which further causes energy consumption.

### SUMMARY

In embodiments of the present disclosure, a memory is driven under a relatively low voltage to realize a reading process.

In an embodiment, a memory is provided, including: a memory array; a row decoding circuit configured to apply a word line voltage to a selected word line during a reading operation; a column decoding circuit configured to select a source line connected with a target memory cell based on data of the reading operation, where the target memory cell is connected with the selected word line; and a reading circuit which includes a first input terminal, a second input terminal and a comparison node, where the first input terminal is connected with source lines of the memory cells in the memory array through the column decoding circuit, and is configured to let in a reading current of the target memory cell, the second input terminal is configured to let in a base current, and the comparison node is configured to compare the reading current with a reference current to output a reading result, where the reference current is related to the base current.

Optionally, the memory array includes memory cells arranged in rows and in columns; a plurality of word lines, where the memory cells arranged in one row share one word line; a plurality of bit lines, where the memory cells arranged in one column share one bit line; and a plurality of source lines, where the memory cells arranged in one column share one bit line and the memory cells arranged in different columns are connected with different bit lines.

Optionally, the memory cells in the memory array may share one bit line.

Optionally, the column decoding circuit may include N source-drain series N-Mental-Oxide-Semiconductor (NMOS) transistors including a 1^{st} NMOS transistor to a N^{th} NMOS transistor, that is, source electrodes of the N NMOS transistors are connected in series, and drain electrodes of the N NMOS transistors are connected in series, where the drain electrode of the 1^{st} NMOS transistor is connected with a source line of a corresponding memory cell, the source electrode of the N^{th} NMOS transistor is connected with the first input terminal, and N is a natural number greater than or equal to 2.

Optionally, the reading circuit may further include: a current mirror circuit, which includes a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and a comparison amplifier, where the comparison amplifier includes a positive terminal configured to let in a base voltage, a negative terminal which is connected with the comparison node and configured to let in a comparison voltage of the comparison node, where the comparison voltage is related to the reference current flowing from the comparison node which is generated by the reading current flowing into the comparison node, and a comparison output terminal configured to output the reading result based on the comparison voltage and the base voltage.

In an embodiment, a circuit for reading a memory is provided, where the memory includes a memory array and a column decoding circuit, and the circuit for reading the memory includes: a first input terminal, which is connected with a source lines of memory cells through the column decoding circuit and configured to let in a reading current of a target memory cell; a second input terminal, configured to let in a base current; a comparison node, configured to compare the reading current with a reference current to output a reading result, where the reference current is related to the base current.

Optionally, the circuit for reading the memory may further include: a current mirror circuit, which includes a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and a comparison amplifier, where the comparison amplifier includes a positive terminal configured to let in a base voltage, a negative terminal which is connected with the comparison node and configured to let in a comparison voltage of the comparison node, where the comparison voltage is related to the reference current flowing from the comparison node which is generated by the reading current flowing into the comparison node, and a comparison output terminal configured to output the reading result based on the comparison voltage and the base voltage.

In an embodiment, a method for reading a memory is provided, where the memory is any one of the above mentioned memories, and the method includes: applying a word line voltage through a row decoding circuit to a word line which is connected with a target memory cell; applying a bit line voltage to a bit line which is connected with the target memory cell; selecting a source line connected with the target memory cell through a column decoding circuit to obtain a reading current at a first input terminal; letting in a base current through the second input terminal; and obtaining a reading result based on the comparison node.

Optionally, the bit line voltage may be within a range from 0.9V to 1.1V.

Embodiments of the present disclosure may have following advantages. In existing techniques, in a memory, a reading voltage or a reading current of a target memory cell is obtained through a bit line of the target memory cell. In embodiments of the present disclosure, the reading voltage or the reading current is obtained through the source line in the memory. The voltage of the power supply of the memory is directly applied to the bit line of the target memory cell, which may greatly decrease the voltage of the power supply (the bit line voltage) required in the reading operation.

Besides, in embodiments of the present disclosure, the column decoding circuit is different from that in the existing techniques. In the existing techniques, the column decoding circuit selects a memory cell by selecting a bit line. In embodiments of the present disclosure, the column decoding circuit is connected with the source lines of the memory cells, and selects a memory cell by providing a low electric level to the source lines of the memory cells. Further, the column decoding circuit consists of a plurality of NMOS transistors. As source electrodes of the NMOS transistors are provided with the low electric level, the control terminals of the NMOS transistors are driven by the low electric level, which may reduce energy consumption.

Besides, in embodiments of the present disclosure, only the bit lines of the memory cells need to be applied with a bit line voltage, thus, a pre-charging circuit is not required in a reading circuit. That is, no pre-charging stage is required in a reading process, which may greatly improve a reading rate of the memory and further reduce energy consumption.

### BRIEF DESCRIPTION OF THE DRAWINGS

FIG. 1 illustrates a structural diagram of a memory array in a memory in existing techniques;

FIG. 2 illustrates a structural diagram of a reading circuit in a memory in existing techniques;

FIG. 3 illustrates a structural diagram of a memory and a reading circuit thereof according to an embodiment of the present disclosure; and

FIG. 4 illustrates a structural diagram of a memory array in a memory according to an embodiment of the present disclosure.

### DETAILED DESCRIPTION

In order to clarify the objects, characteristics and advantages of the disclosure, embodiments of present disclosure will be described in detail in conjunction with accompanying drawings.

Many details are described in following description to better understand the present disclosure. It should be noted that, the following embodiments are only illustrative. Those skilled in the art can modify and vary the embodiments without departing from the spirit and scope of the present disclosure.

As described in the background, in the existing techniques, a circuit for reading a memory is always driven by a high voltage VDD of a power supply.

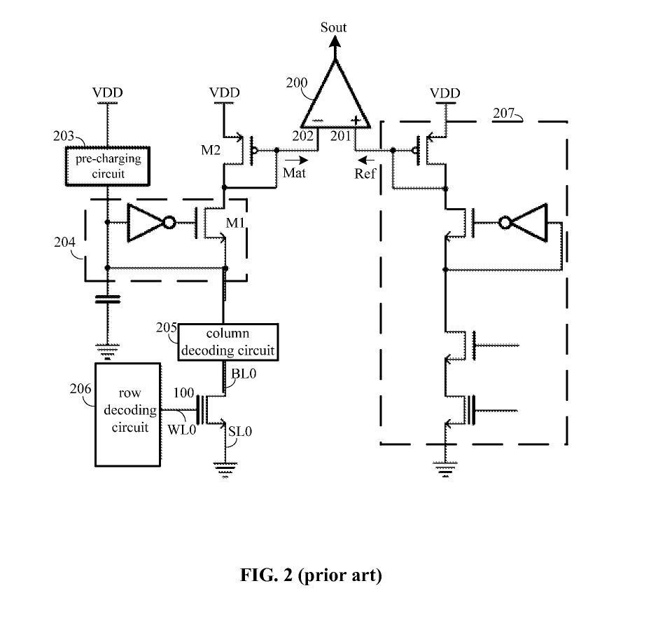

Referring to FIG. 2, when the voltage VDD is decreased, a clamping voltage is decreased, then, a bit line voltage of a selected memory cell is decreased, and a current generated by the memory cell is decreased. As a result, a reading rate of the memory is impacted, and the bit line voltage may be obtained inaccurately, thereby causing failure in reading data. Besides, when the voltage VDD is decreased, signals at control terminals of series transistors in the column decoding circuit 205 are further weaken, which results in a lower reading rate of the memory. In practice, threshold voltages of transistors in a column decoding circuit may be different from one another, which may affect reading accuracy of data.

However, reading circuits are designed to have a high rate and low consumption to accommodate the trend in downsizing of memory sizes. When sizes of circuits and structures in a memory are reduced, the voltage of the power supply is reduced accordingly. Therefore, the reading circuit in the conventional memory does not conform the trend.

To enable a memory to better accommodate a relatively low driving voltage of a power supply, a memory is provided in an embodiment, which may realize fast reading under a relatively low voltage of a power supply.

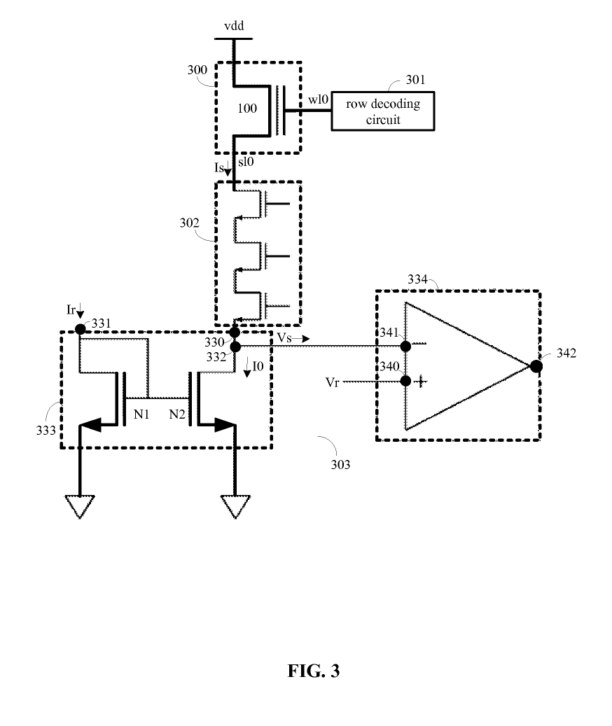

Referring to FIG. 3, the memory includes: a memory array 300; a row decoding circuit 301 configured to apply a word line voltage to a selected word line wl0 during a reading operation, where the word line voltage is a voltage required to be applied to the selected word line in the reading operation; a column decoding circuit 302 configured to select a source line sl0 connected with a target memory cell 100 based on data of the reading operation, where the target memory cell 100 is connected with the selected word line wl0; and a reading circuit 303 which includes a first input terminal 330, a second input terminal 331 and a comparison node 332, where the first input terminal 330 is connected with source lines of memory cells through the column decoding circuit 302 and configured to let in a reading current of the target memory cell 100 (i.e., a source line current Is), the second input terminal 331 is configured to let in a base current Ir, and the comparison node 332 is configured to compare the reading current with a reference current I0 to output a reading result, where the reference current I0 is related to the base current Ir.

In some embodiments, the reference current I0 may be equal to the base current Ir, or may be proportional to the base current Ir, or may have a function relation with the base current Ir.

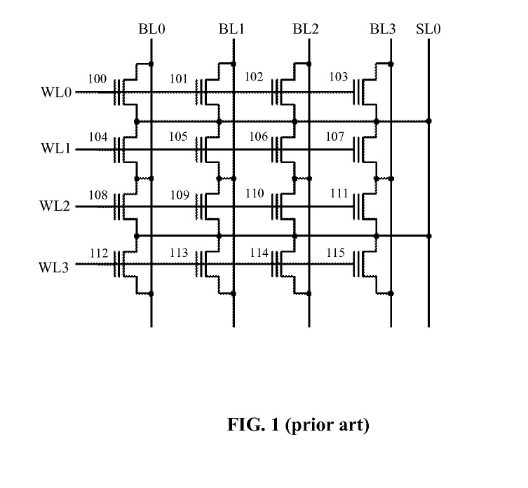

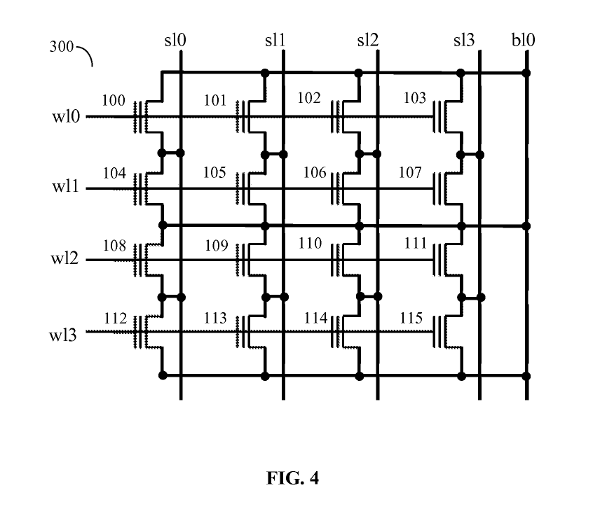

Referring to FIG. 4, a detailed structure of the memory array 300 is different from that in FIG. 1. The memory array 300 includes memory cells 100 to 115. The memory cells 100 to 103 are arranged in one row, the memory cells 104 to 107 are arranged in one row, the memory cells 108 to 111 are arranged in one row, and the memory cells 112 to 115 are arranged in one row. The memory cells 100, 104, 108 and 112 are arranged in one column, the memory cells 101, 105, 109 and 113 are arranged in one column, the memory cells 102, 106, 110 and 114 are arranged in one column, and the memory cells 103, 107, 111 and 115 are arranged in one column.

The memory array 300 further includes word lines wl0 to wl3, source lines sl0 to sl3 and one bit line bl0. The memory cells in one row share one word line, the memory cells in one column share one bit line, and the memory cells 100 to 115 share the bit line bl0.

From FIG. 4, the memory cells are arranged in rows and in columns in the memory array, and the memory cells share one common drain electrode. The common drain electrode is provided with a voltage of a power supply or a driving voltage directly. In some embodiments, the memory cells share one bit line. In some conventional memory arrays, memory cells in one column share one bit line. In embodiments of the present disclosure, some improvement may be made on the conventional memory arrays, for example, all the bit lines may be connected in parallel to be accessed to the same voltage of the power supply to obtain the bit line voltage. That is, in some embodiments, the memory may include a plurality of bit lines, the memory cells in one column share one bit line, and the plurality of bit lines are connected in parallel.

Therefore, at least two kinds of memory array are provided in embodiments of the present disclosure.

The first kind of memory array includes memory cells arranged in rows and in columns, a plurality of word lines, a plurality of bit lines and a plurality of source lines. The memory cells arranged in one row share one word line. The memory cells arranged in one column share one bit line and the memory cells arranged in different columns are connected with different bit lines. The memory cells arranged in one column share one source line and the memory cells arranged in different columns are connected with different source lines.

The second kind of memory array includes memory cells arranged in rows and in columns, a plurality of word lines, one bit line and a plurality of source lines. The memory cells arranged in one row share one word line. All the memory cells share one bit line, that is, not only the memory cells arranged in one column share one bit line but also the memory cells arranged in different columns share one bit line. The memory cells arranged in one column share one source line and the memory cells arranged in different columns are connected with different source lines.

For example, the memory cell 100 is the target memory cell. In the first kind of memory array, the plurality of bit lines may be connected in parallel. During the reading operation, a bit line voltage is provided to the bit lines directly. A word line voltage is applied to the selected word line wl0 through the row decoding circuit 301, the source line sl0 connected with the memory cell 100 is selected by the column decoding circuit 302, and a source line voltage (low electric level) is provided to the source line sl0. In this manner, the memory cell 100 is selected, and a source line current Is, which is also called a reading current, is output from the source line sl0. In the second kind of memory array, all the memory cells share one bit line. During the reading operation, a bit line voltage is provided to the bit line directly, and the memory cell 100 is selected following a similar process described in the first kind of memory array.

Still referring to FIG. 3, the column decoding circuit 302 includes N source-drain series NMOS transistors including a 1^{st} NMOS transistor to a N^{th} NMOS transistor, where the drain electrode of the 1^{st} NMOS transistor is connected with a source line of a corresponding memory cell, the source electrode of the N^{th} NMOS transistor is connected with the first input terminal 330, and N is a natural number greater than or equal to 2. In some embodiments, N is 3.

In some embodiments, the column decoding circuit 302 may include one NMOS transistor (not shown), whose drain electrode is connected with a source line of a corresponding memory cell and whose source electrode is connected with the first input terminal 330.

Still referring to FIG. 3, the reading circuit 303 further includes a current mirror circuit 333, which includes a current mirror consisting of a first NMOS transistor N1 and a second NMOS transistor N2, where a drain electrode of the first NMOS transistor N1 is connected with the second input terminal 331, a drain electrode of the second NMOS transistor N2 is connected with the first input terminal 330, and the comparison node 332 is a connection node between the drain electrode of the second NMOS transistor N2 and the first input terminal 330.

It can be known from the above structure, a current from the drain electrode to the source electrode in the second NMOS transistor N2 is the reference current M. The reference current I0 is a mirror current of a current from the drain electrode to the source electrode in the first NMOS transistor N1, i.e., a mirror current of the base current Ir. Thus, the reference current I0 is proportional to the base current Ir, and the proportion is related to a ratio of a size of the first NMOS transistor N1 to a size of the second NMOS transistor N2.

The comparison node 332 generates a comparison current or a comparison voltage based on the source line current Is let in by the first input terminal 330 and the reference current M. The comparison current is (Is−I0). The comparison voltage is related to the source line current Is flowing into the comparison node 332 and the reference current I0 output from the comparison node 332.

In some embodiments, the reading result of the selected memory cell may be related to the comparison current or the comparison voltage.

In some embodiments, the reading result of the selected memory cell is related to the comparison current. The reading circuit may further include an inverting amplifier unit consisting of a plurality of inverting amplifiers connected in series. The inverting amplifier unit is configured to let in the comparison current and amplify the comparison signal to realize data reading.

In some embodiments, the reading result of the selected memory cell is related to the comparison voltage. The reading circuit may further include a comparison amplifier 334. Referring to FIG. 3, the comparison amplifier 334 includes a positive terminal 340 configured to let in a base voltage Vr, a negative terminal 341 which is connected with the comparison node 332 and configured to let in the comparison voltage Vs of the comparison node 332, and a comparison output terminal 342 configured to output the reading result based on the compassion voltage Vs and the base voltage Vr.

In embodiments of the present disclosure, no pre-charging stage is required in the reading process. When the reading operation of the memory starts, the voltage Vdd of the power supply is provided, that is, the bit line voltage (i.e., the voltage Vdd) is applied to the bit lines connected with the memory cells. At the same time, the row decoding circuit 301 applies the word line voltage to the word line connected with the target memory cell, and the column decoding circuit 302 connects the source line which is connected with the target memory cell to a low electric level to obtain the reading current (source current).

The above process is actually a power-on process of the memory. No pre-charging stage for the bit lines is required, and the bit lines in the memory array are applied with the voltage Vdd of the power supply directly, which may greatly improve the reading rate of the memory.

The voltage of the power supply required in the memory in embodiments of the present disclosure is further compared with that in the existing techniques.

Referring to FIG. 2, in the conventional memory, to perform a reading operation, a bit line voltage, i.e., a voltage of a power supply, should be greater than or equal to (Vdr+Vds1+Vds2) (detailed description can be found in the background). For example, a source-drain voltage difference Vds1 of the first control transistor M1 is 0.1V, a source-drain voltage difference Vds2 of the second control transistor M2 is 0.6V (for example, the second control transistor M2 has a threshold voltage of 0.4V and an over-driving voltage 0.2V), and a difference Vdr between a source line voltage and a bit line voltage of the target memory cell 100 is 0.7V, thus, the voltage of the power supply should be maintained at least at 1.4V.

Referring to FIG. 3, in embodiments of the present disclosure, the voltage Vdd of the power supply to be provided is only required to reach the voltage difference Vdr between the source line voltage and the bit line voltage of the target memory cell 100. For example, the difference Vdr between the source line voltage and the bit line voltage of the target memory cell 100 is 0.7V, thus, the voltage Vdd of the power supply of the memory should be greater than or equal to 0.7V. In some embodiments, the voltage of the power supply may be within a range from 0.9V to 1.1V, which can meet driving requirements of a low voltage of power supply. It can be understood by those skilled in the art, in some embodiments, the memory may be read under a high voltage of a power supply.

In an embodiment, a circuit for reading the above memory is provided, including: a first input terminal, which is connected with a source line of a memory cell through a column decoding circuit in the memory and configured to let in a reading current of a target memory cell; a second input terminal, configured to let in a base current; a comparison node, configured to compare the reading current with a reference current to output a reading result, where the reference current is related to the base current.

In some embodiments, the circuit for reading the memory may further include: a current mirror circuit, which includes a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and a comparison amplifier, where the comparison amplifier includes a positive terminal configured to let in a base voltage, a negative terminal which is connected with the comparison node and configured to let in a comparison voltage of the comparison node, where the comparison voltage is related to a reference current flowed from the comparison node which is generated by the reading current flowing over the comparison node, and a comparison output terminal configured to output the reading result based on the compassion voltage and the base voltage.

In an embodiment, a method for reading a memory is provided, including S100 to S104.

In S100, a word line voltage is applied through a row decoding circuit of the memory to a word line which is connected with a target memory cell.

In S101, a bit line voltage is applied to a bit line which is connected with the target memory cell.

In some embodiments, the bit line voltage may be equal to a voltage of power supply. In some embodiments, the bit line voltage may be within a range from 0.9V to 1.1V. It should be noted that, the bit line voltage (the voltage of the power supply) in the method may be not limited to a low electric level voltage, such as the range from 0.9V to 1.1V. In some embodiments, the bit line voltage may be a high electric level voltage.

In S102, a source line connected with the target memory cell is selected through a column decoding circuit, to obtain a reading current at a first input terminal.

In S103, a base current is let in through the second input terminal.

In S104, a reading result is obtained based on the comparison node.

It should be noted that, S100, S101 and S102 belong to a power-on process of the memory. Thus, they may be performed in any sequence. In some embodiments, S101 is performed when the memory is applied with the voltage of power supply. S100 and S102 are steps for selecting the target memory cell. When the memory cells are read, S101 may be performed once while S100 and S102 may be performed repeatedly.

From above, the method for reading the memory is different from that in the existing techniques.

In the existing techniques, except for the power-on process of the memory, a memory reading process further includes a pre-charging stage and a comparison stage. During the memory reading process, the power-on process of the memory is performed only one time. When the memory cells in the memory are selected and data therein are read, the pre-charging stage and the comparison stage are performed repeatedly according to target memory cells selected.

In embodiments of the present disclosure, the memory reading process includes the power-on process of the memory and the comparison stage. From S100 to S104, S101 needs to be performed one time actually. As the reading process does not include a pre-charging stage, when the memory cells are selected and data thereof are read, only steps for selecting the memory cells and the comparison steps are performed repeatedly. As a result, energy consumption may be reduced, and the reading rate may be improved.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure. Therefore, the protection scope of the present disclosure is subject to the scope defined by the claims.

What is claimed is:

1. A memory, comprising:
a memory array;
a row decoding circuit configured to apply a word line voltage to a selected word line during a reading operation;
a column decoding circuit configured to select a source line connected with a target memory cell based on data of the reading operation, where the target memory cell is connected with the selected word line; and
a reading circuit which comprises a first input terminal, a second input terminal and a comparison node, where the first input terminal is connected with source lines of the memory cells in the memory array through the column decoding circuit, and is configured to let in a reading current of the target memory cell, the second input terminal is configured to let in a base current, and the comparison node is configured to compare the reading current with a reference current to output a reading result, where the reference current is related to the base current.

2. The memory according to claim 1, wherein the memory array comprises:
memory cells arranged in rows and in columns;
a plurality of word lines, where the memory cells arranged in one row share one word line;
a plurality of bit lines, where the memory cells arranged in one column share one bit line; and
a plurality of source lines, where the memory cells arranged in one column share one bit line and the memory cells arranged in different columns are connected with different bit lines.

3. The memory according to claim 2, wherein the memory cells in the memory array share one bit line.

4. The memory according to claim 1, wherein the column decoding circuit comprises N source-drain series N-Mental-Oxide-Semiconductor (NMOS) transistors comprising a 1^{st} NMOS transistor to a N^{th} NMOS transistor,
where the drain electrode of the 1^{st} NMOS transistor is connected with a source line of a corresponding memory cell, the source electrode of the N^{th} NMOS transistor is connected with the first input terminal, and N is a natural number greater than or equal to 2.

5. The memory according to claim 1, wherein the reading circuit further comprises:
a current mirror circuit, which comprises a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and
a comparison amplifier, comprising:
a positive terminal configured to let in a base voltage;
a negative terminal which is connected with the comparison node and configured to let in a comparison voltage of the comparison node, where the comparison voltage is related to the reference current flowing from the comparison node which is generated by the reading current flowing into the comparison node; and
a comparison output terminal configured to output the reading result based on the compassion voltage and the base voltage.

6. A circuit for reading a memory, where the memory comprises a memory array and a column decoding circuit, and the circuit for reading the memory comprises:
a first input terminal, which is connected with source lines of memory cells through the column decoding circuit and configured to let in a reading current of a target memory cell;
a second input terminal, configured to let in a base current;
a comparison node, configured to compare the reading current with a reference current to output a reading result, where the reference current is related to the base current.

7. The circuit for reading the memory according to claim 6, further comprising:
a current mirror circuit, which comprises a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and
a comparison amplifier, comprising:
a positive terminal configured to let in a base voltage;
a negative terminal which is connected with the comparison node and configured to let in a comparison voltage of the comparison node, where the comparison voltage is related to the reference current flowing from the comparison node which is generated by the reading current flowing into the comparison node; and
a comparison output terminal configured to output the reading result based on the compassion voltage and the base voltage.

8. A method for reading a memory, where the memory comprises:
a memory array;
a row decoding circuit configured to apply a word line voltage to a selected word line during a reading operation;
a column decoding circuit configured to select a source line connected with a target memory cell based on data of the reading operation, where the target memory cell is connected with the selected word line; and
a reading circuit which comprises a first input terminal, a second input terminal and a comparison node, where the first input terminal is connected with source lines of the memory cells in the memory array through the column decoding circuit, and is configured to let in a reading current of the target memory cell, the second input terminal is configured to let in a base current, and the comparison node is configured to compare the reading current with a reference current to output a reading result, where the reference current is related to the base current, and
the method comprises:
applying the word line voltage through the row decoding circuit to the selected word line which is connected with the target memory cell;
applying a bit line voltage to a bit line which is connected with the target memory cell;
selecting the source line connected with the target memory cell through the column decoding circuit to obtain the reading current at the first input terminal;
letting in the base current through the second input terminal; and
obtaining the reading result based on the comparison node.

9. The method according to claim 8, wherein the memory array comprises:
memory cells arranged in rows and in columns;
a plurality of word lines, where the memory cells arranged in one row share one word line;
a plurality of bit lines, where the memory cells arranged in one column share one bit line; and
a plurality of source lines, where the memory cells arranged in one column share one bit line and the memory cells arranged in different columns are connected with different bit lines.

10. The method according to claim 9, wherein the memory cells in the memory array share one bit line.

11. The method according to claim 8, wherein the column decoding circuit comprises N source-drain series NMOS transistors comprising a 1^{st} NMOS transistor to a N^{th} NMOS transistor,
where the drain electrode of the 1^{st} NMOS transistor is connected with a source line of a corresponding memory cell, the source electrode of the N^{th} NMOS transistor is connected with the first input terminal, and N is a natural number greater than or equal to 2.

12. The method according to claim 8, wherein the reading circuit further comprises:
a current mirror circuit, which comprises a current mirror consisting of a first NMOS transistor and a second NMOS transistor, where a drain electrode of the first NMOS transistor is connected with the second input terminal, a drain electrode of the second NMOS transistor is connected with the first input terminal, and the comparison node is a connection node between the drain electrode of the second NMOS transistor and the first input terminal; and
a comparison amplifier, comprising:
a positive terminal configured to let in a base voltage;
a negative terminal which is connected with the comparison node and configured to let in a comparison voltage of the comparison node, where the comparison voltage is related to the reference current flowing from the comparison node which is generated by the reading current flowing into the comparison node; and
a comparison output terminal configured to output the reading result based on the compassion voltage and the base voltage.

13. The method according to claim 8, wherein the bit line voltage is within a range from 0.9V to 1.1V.
